(19) United States
(12) Patent Application Publication
(10) Pub. No.: US 2001/0029108 A1
(43) Pub. Date: Oct. 11, 2001

(54) Substrate processeing apparatus, substrate processing method and electronic device manufacturing method

(76) Inventor: Kouji Tometsuka, Tokyo (JP)

Correspondence Address: Hogan & Hartson L.L.P., Suite 1900, Biltmore Tower, 500 S. Grand Ave., Los Angeles, CA, 90071, US

(21) Appl. No.: 09/799,816

(22) Filed: Mar. 5, 2001

(30) Foreign Application Priority Data
Mar. 6, 2000 (JP) 2000-60875

(51) Int. Cl. H01L 21/31

(52) U.S. Cl. 438/770

(57) ABSTRACT

A substrate processing apparatus includes a process be for forming a processing chamber provided at its lower end with a furnace port, a boat for going in and out from the processing chamber to transfer a substrate or substrates into and out from the processing chamber, a chamber forming a eliminary chamber and disposed below the processing tube for staying the boat on standby, a seal flange disposed between the processing chamber and the preliminary chamber and having opening through which the boat passes, and a seal lid detachably disposed on the seal flange at the side of the processing chamber for seating on the seal flange to air-tightly close the opening.

### BACKGROUND OF THE INVENTION

1. Field of the Invention

The present invention relates to a substrate processing apparatus, a substrate processing method and an electronic device manufacturing method, and more particularly, to an oxidation and contamination preventing technique for a substrate which is subjected to processing in an air-tightly closed processing chamber and for example, the invention can effectively be utilized for carrying out, for a semiconductor wafer, oxide film forming processing or diffusion processing, anneal processing and film forming processing in a producing process of a semiconductor device.

2. Description of the Related Art

In general, in a producing process of a semiconductor device, a batch-type vertical-type hot wall-type substrate processing apparatus is widely used for carrying out the oxide film forming processing or the diffusion processing, the anneal processing and the film forming processing for a semiconductor wafer (wafer, hereinafter).

For example, the batch-type vertical-type hot wall-type substrate processing apparatus (heat treatment apparatus, hereinafter) for carrying out heat treatment such as the oxide film forming processing or the diffusion processing, and the anneal processing comprises a vertically disposed process tube for forming a processing chamber into which wafers are to be transferred, a gas introducing port for introducing gas into the processing chamber, an exhaust tube for evacuating the processing chamber to produce a vacuum. and a heater disposed outside the process tube for heating the processing chamber. A plurality of wafers are transferred into the processing chamber from a lower end furnace port in a state in which the wafers are concentrically arranged and held by a boat, the processing chamber is heated by the heater, and the heat treatment such as the oxide film forming processing or the diffusion processing, and the anneal processing is carried out.

In the conventional heat treatment apparatus, the wafers before they are transferred into the processing chamber or after they were transferred out from the processing chamber are in contact with atmosphere, and undergo oxidation due to oxygen or moisture included in the atmosphere. Therefore, there is a problem that unnecessary oxide film is formed on the wafer, and precision of processing such as the oxide film forming processing, the diffusion processing, and the anneal processing is lowered.

Thereupon, there has been proposed a heat treatment apparatus comprising a chamber formed with a preliminary chamber in which a boat stays on standby below a process tube, and inert atmosphere is formed in the preliminary chamber. In this heat treatment apparatus, wafers held by the boat which stays in the preliminary chamber on standby before the wafers are transferred into the processing chamber and after the wafers are transferred out from the processing chamber are placed in the inert atmosphere. Therefore, the wafers do not undergo oxidation by oxygen or moisture included in the atmosphere. As a result, unnecessary oxide film is not formed on the wafers, and the problem that precision of processing is lowered is avoided.

However, in the heat treatment apparatus having the preliminary chamber for forming the inert atmosphere, since a gate valve is mounted for partitioning the processing chamber and the preliminary chamber during the standby state of the boat in the preliminary chamber, there are problems that dust is generated when the gate valve is opened and closed, and the heat treatment apparatus producing cost and running cost are increased.

### SUMMARY OF THE INVENTION

It is an object of the present invention to provide a substrate processing apparatus and a substrate processing method capable of enhancing precision of substrate processing while preventing dust from being generated and preventing costs from being increased.

According to a first aspect of the present invention, there is provided a substrate processing apparatus, comprising:

a process tube for forming a processing chamber provided at its lower end with a furnace port;

a boat for going in and out from the processing chamber to transfer a substrate or substrates into and out from the processing chamber;

a chamber forming a preliminary chamber and disposed below the processing tube for staying the boat on standby, a seal flange disposed between the processing chamber and the preliminary chamber and having an opening through which the boat passes; and

a seal lid detachably disposed on the seal flange at the side of the processing chamber for seating on the seal flange to air-tightly close the opening.

In accordance with the substrate processing apparatus according to the first aspect of the present invention, when a boat stays in the preliminary chamber on standby, since the seal lid is seated on the seal flange to close the opening of the seal flange, the preliminary chamber can form inert atmosphere. When the boat is transferred into the processing chamber from the preliminary chamber, the boat lifts the seal lid, and the seal lid is automatically separated from the seal flange. That is, a driving apparatus is not required for opening and closing the opening of the seal flange by the seal lid. Therefore, no dust is generated by the driving apparatus, and it is unnecessary to increase the producing cost and running cost for the driving apparatus.

According to a second aspect of the present invention, there is provided a substrate processing method comprising the step of processing a substrate or substrates using a substrate processing apparatus, comprising:

a process tube for forming a processing chamber provided at its lower end with a furnace port;

a boat for going in and out from the processing chamber to transfer the substrate or the substrates into and out from the processing chamber;

a chamber forming a preliminary chamber and disposed below the processing tube for staying the boat on standby, a seal flange disposed between the processing chamber and the preliminary chamber and having an opening through which the boat passes; and

a seal lid detachably disposed on the seal flange at the side of the processing chamber for seating on the seal flange to air-tightly close the opening.

According to a third aspect of the present invention, there is provided an electronic device manufacturing method comprising the step of processing a substrate or substrates using a substrate processing apparatus, comprising:

a process tube for forming a processing chamber provided at its lower end with a furnace port;

a boat for going in and out from the processing chamber to transfer the substrate or the substrates into and out from the processing chamber;

a chamber forming a preliminary chamber and disposed below the processing tube for staying the boat on standby, a seal flange disposed between the processing chamber and the preliminary chamber and having an opening through which the boat passes; and

a seal lid detachably disposed on the seal flange at the side of the processing chamber for seating on the seal flange to air-tightly close the opening.

Preferable examples of the electronic devices manufactured by this methods includes a semiconductor device and a liquid crystal display device.

### BRIEF DESCRIPTION OF THE DRAWINGS

The above and further objects, features and advantages of the present invention will become more apparent from the following detailed description taken in conjunction with the accompanying drawings, wherein:

FIG. 1 is a front sectional view showing a heat treatment apparatus according to one embodiment of the present invention;

FIG. 2 is a front sectional view showing a state in which substrates are being processed using the heat treatment apparatus shown in FIG. 1;

FIG. 3A is a perspective view, FIG. 3B is a front view and FIG. 3C is a plan view each showing a seal lid; and

FIG. 4 is a front sectional view showing a heat treatment apparatus according to another embodiment of the present invention.

### DESCRIPTION OF THE PREFERRED EMBODIMENTS

One embodiment of the present invention will be explained referring to the drawings.

In the present embodiment, a substrate processing apparatus according to the present invention is constructed as a batch-type vertical-type hot wall-type substrate processing apparatus (heat treatment apparatus, hereinafter) for carrying out heat treatment such as oxide film forming processing or diffusion processing and anneal processing and is used for carrying out, for a wafer as a substrate, a heat treatment method such as the oxide film forming processing or the diffusion processing and the anneal processing.

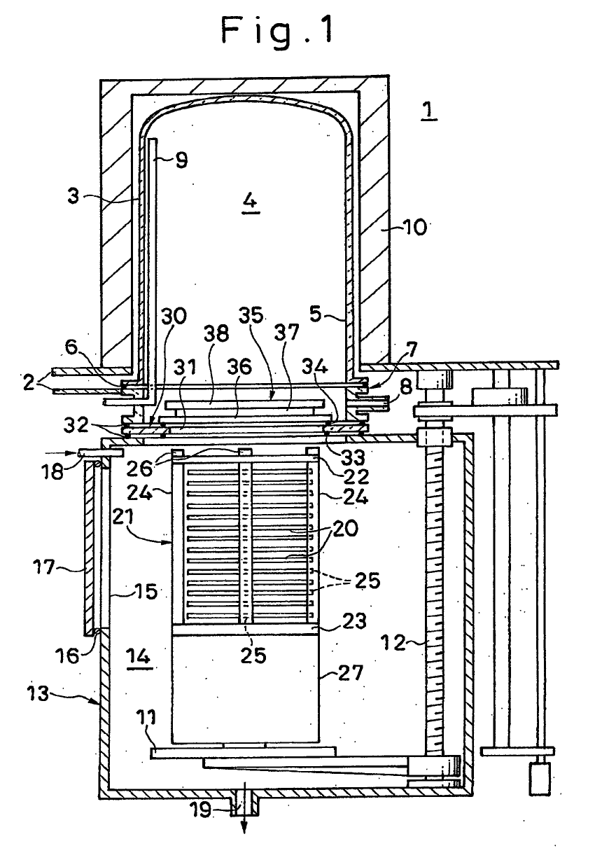

As shown in FIG. 1, a heat treatment apparatus 1 includes a vertical process tube 3 which is supported by a machine frame (only a portion thereof is shown) 2 and disposed such that a center line thereof is directed vertically. The process tube 3 is made of quartz and integrally formed into a cylindrical shape whose lower end is opened. A cylindrical hollow portion of the process tube 3 forms a processing chamber 4. A plurality of wafers concentrically arranged and held by a boat are transferred into the processing chamber 4. The lower end opening of the process tube 3 is formed as a furnace port 5 through which the wafers, as substrates to be processed, are transferred into and out from the processing chamber 4. Therefore, an inner diameter of the process tube 3 is set larger than a maximum outer diameter of the wafers to be handled.

A lower end face of the process tube 3 is in abutment against an upper end surface of a manifold 7 with a seal ring 6 interposed therebetween. The manifold 7 is supported by the machine frame 2 of the heat treatment apparatus 1 so that the process tube 3 is vertically supported.

An exhaust port 8 for evacuating the processing chamber 4 to produce a predetermined vacuum is formed at a portion of a side wall of the manifold 7. The exhaust port 8 is in communication with the processing chamber 4. A gas introducing tube 9 is inserted in a position opposed to the exhaust port 8 in the side wall of the manifold 7. An insertion end of the gas introducing tube 9 extends to an upper end of the processing chamber 4. A supply source of processing gas and a supply source of inert gas (both not shown) are to be connected to the gas introducing tube 9. Gas introduced into the processing chamber 4 by the gas introducing tube 9 is exhausted by the exhaust port 8.

A heater unit 10 is concentrically disposed such as to surround the process tube 3 outside the process tube 3, and the heater unit 10 is configured so as to uniformly heats inside of the processing chamber 4 entirely. The machine frame 2 of the heat treatment apparatus supports the heater unit 10 so that the heater unit 10 is mounted vertically.

A disc-like cap 11 having substantially the same diameter as the outer diameter of the process tube 3 is concentrically disposed directly below the process tube 3. The cap 11 is hoisted and lowered in the vertical direction by an elevator 12 comprising a feed screw mechanism. A boat 21 for holding wafers 20 as substrates to be processed stands vertically on a centerline of the cap 11, and is supported on the cap 11.

The boat 21 includes a pair of upper and lower end plates 22 and 23, and a plurality of holding members 24 bridged between both the end plates 22 and 23 and vertically disposed. Each of the holding members 24 is provided with a plurality of holding grooves 25 which are disposed at an equal distance in a longitudinal direction of the holding member 24 such that the holding grooves 25 are opened on a same plane. The plurality of wafers 20 are horizontally arranged and held such that centers of the wafers 20 are aligned by inserting the wafers 20 between the holding grooves 25 of the holding members 24. An abutment portion 26 which abuts against a seal lid (this will be described latter) is projecting from an upper surface of the upper end plate 22 of the boat 21. A heat insulating cap 27 is formed below the lower end plate 23 of the boat 21.

A load lock chamber (chamber, hereinafter) 13 is formed below the process tube 3. The chamber 13 forms a preliminary chamber 14 in which the boat 21 stays on standby in a lower space of the process tube 3. A wafer load-unload port 15 is formed in one sidewall of the chamber 13. The wafer load-unload port 15 is opened and closed by a gate valve 17 through a seal ring 16. A gas introducing tube 18 for introducing inert gas such as nitrogen is inserted in an upper portion of the sidewall of the chamber 13. An exhaust port 19 for evacuating the preliminary chamber 14 is formed in a bottom wall of the chamber 13, and a vacuum apparatus (not shown) such as a vacuum pump is connected to the exhaust port 19.

In the present embodiment, a seal flange 30 provided at its central portion with an opening 31 is sandwiched between a ceiling wall upper surface of the chamber 13 and a lower surface of the manifold 7 respectively through seal rings 32 and 32. The seal flange 30 is made of quartz and formed into a circle ring shape. The opening 31 is formed by an inner diameter portion of the ring. An inner diameter of the opening 31 of the seal flange 30 is set larger than an outer diameter of the boat 21 so that the boat 21 can pass therethrough. The seal flange 30 is disposed such that the center of the opening 31 coincides with centerlines of the process tube 3 and the cap 11. A seal ring 33 for forming a sealed state between the cap 11 and the seal flange 30 is disposed on a lower surface of the seal flange 30 such as to surround the opening 31.

A seal lid 35 is detachably disposed on an upper surface of the seal flange. 30 at the side of the processing chamber 4 with a seal ring 34 sandwiched therebetween. In a state in which the seal lid 35 is seated on the upper surface of the seal flange 30 and sandwiches the seal ring 34 between the seal lid 35 and the upper surface of the seal flange 30, the seal lid 35 closes the opening 31 of the seal flange 30.

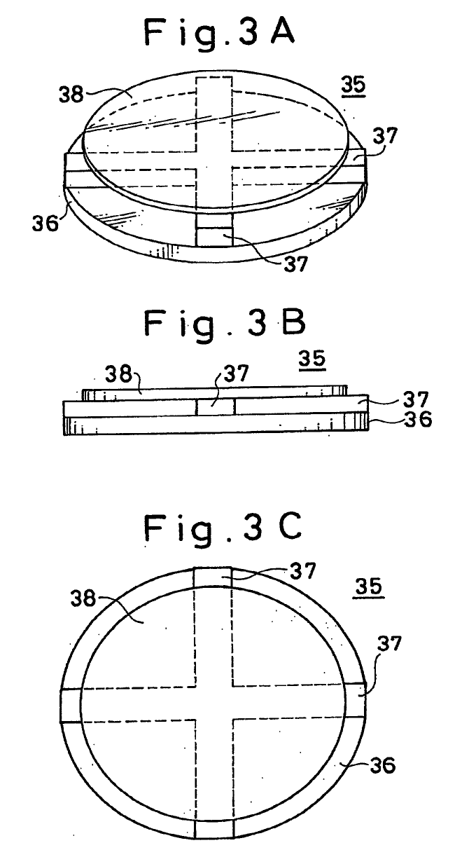

As shown in FIG. 3, the seal lid 35 includes a seal portion 36, a rib portion 37 and a heat insulating portion 38, and all of them are made of quartz. The seal portion 36 is formed into a disc-like shape whose outer diameter is larger than in inner diameter of the opening 31 of the seal flange 30 and smaller than an inner diameter of the processing chamber 4. The opening 31 of the seal flange 30 is closed in a sealed state by seating the seal ring 34 on an upper surface of the seal flange 30 with the seal ring 34 sandwiched therebetween. The rib portion 37 comprises two square prisms each having substantially the same length as the outer diameter of the seal portion 36, the square prisms are combined in the shape of a cross and are disposed and welded concentrically on an upper surface of the seal portion 36. The heat-insulating portion 38 is formed into a disc-like shape whose outer diameter is slightly smaller than the outer diameter of the seal portion 36. The heat-insulating portion 38 is concentrically disposed and welded on an upper surface of the rib portion 37. In this state, the rib portion 37 reinforces a mechanical strength of the seal portion 36 and the heat-insulating portion 38.

Next, operation of the heat treatment apparatus having the above-described structure, and a manner for forming an oxide film on a wafer using a wafer heat treatment method of the one embodiment of the present invention will be explained.

As shown in FIG. 1, the plurality of wafers 20 are transferred from the wafer load-unload port 15 by a wafer transferring apparatus (not shown), and inserted into the holding grooves 25 of the boat 21 and held thereby. At that time, since the gate valve 17 opens the wafer load-unload port 15, pressure in the preliminary chamber 14 is increased to be slightly higher than the atmosphere so that atmospheric air is prevented from flowing into the preliminary chamber 14. On the other hand, since it is necessary to prevent ambience of the preliminary chamber 14 from leaking into the processing chamber 4, the opening 31 of the seal flange 30 must be closed in a sealed manner by the seal lid 35. Therefore, pressure in the processing chamber 4 is maintained higher than pressure in the preliminary chamber 14. Thus, nitrogen (N₂) as an inert gas is introduced into the preliminary chamber 14 from the gas introducing tube 18, and nitrogen gas as an inert gas is also introduced into the processing chamber 4 from the gas introducing tube 9.

Since the nitrogen gas ambience is formed in the preliminary chamber 14 in this manner, the wafers 20 do not come into contact with the atmosphere and do not undergo oxidation by oxygen or moisture included in the atmosphere when the wafers 20 are mounted on the boat 21, and unnecessary oxide film is reliably prevented from being formed on the wafers 20.

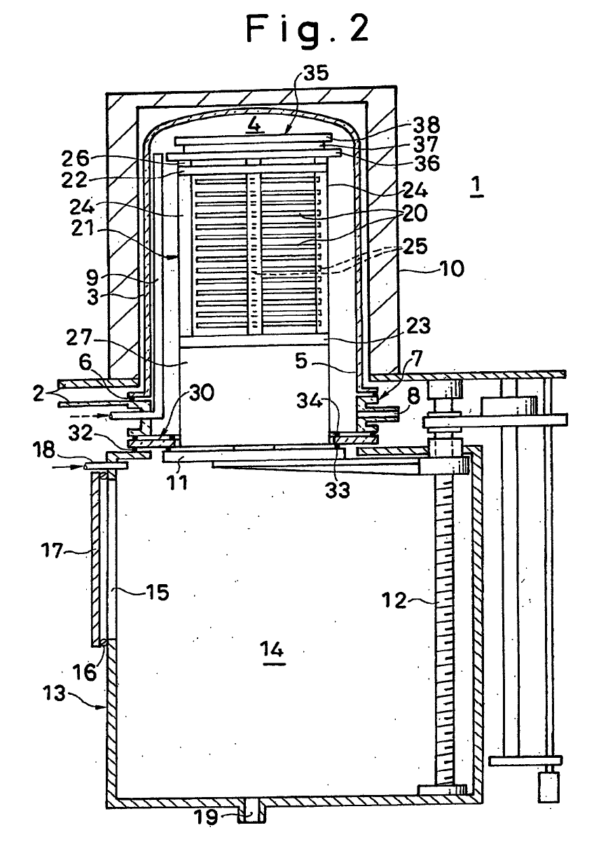

As shown in FIG. 2, a predetermined number of wafers 20 are mounted on the boat 21, and when the wafer load-unload port 15 is closed by the gate valve 17, the boat 21 is hoisted by the elevator 12 and transferred into the processing chamber 4 of the process tube 3. At that time, since the boat 21 is opposed to the seal lid 35 from below, the abutment portion 26 of the boat 21 abuts against the lower surface of the seal portion 36 of the seal lid 35. As the boat 21 is hoisted, the seal lid 35 is separated from the seal flange 30 and then, the boat 21 pushes the seal lid 35 upward.

When the boat 21 pushes the seal lid 35 upward to separate the seal lid 35 from the seal flange 30, if the pressure in the processing chamber 4 is higher than the pressure in the preliminary chamber 14, the seal lid 35 is pushed to force it to be contacted with the seal flange 30 by the pressure difference between the processing chamber 4 and the preliminary chamber 14, and therefore the boat 21 can not easily push the seal lid 35 upward. As a result, the boat 21 can not easily separate the seal lid 35 from the seal flange 30.

Thereupon, in the present embodiment, when the boat 21 separates the seal lid 35 from the seal flange 30, the pressure in the preliminary chamber 14 is adjusted to be equal or greater than the pressure in the processing chamber 4, and the state in which the seal lid 35 is pushed to be contacted with the seal flange 30 by the pressure in the processing chamber 4 is released. The pressure in the preliminary chamber 14 may be adjusted to be equal to or greater than the pressure in the processing chamber 4 by appropriately exhausting the nitrogen gas in the processing chamber 4 from the exhaust port 8, or by increasing the amount of nitrogen gas introduced into the preliminary chamber 14 by the gas introducing tube 18 and the exhaust port 19. Even if the nitrogen gas in the preliminary chamber 14 is allowed to flow into the processing chamber 4 by the pressure difference between the preliminary chamber 14 and the processing chamber 4, since the nitrogen gas is inert gas, the gas does not interfere with the diffusion processing in the processing chamber 4.

If the boat 21 reaches the upper limit, the cap 11 is seated on the lower surface of the seal flange 30 with the seal ring 33 interposed therebetween, and the opening 31 of the seal flange 30 is closed in the sealed state. Therefore, the processing chamber 4 and the preliminary chamber 14 are cut off from each other in terms of fluid. In this state, the seal lid 35 is pushed toward an upper portion of the processing chamber 4 by the boat 21.

In a state in which the processing chamber 4 is air-tightly closed by the cap 11, the processing chamber 4 is evacuated to a predetermined vacuum by the exhaust port 8, the processing chamber 4 is uniformly heated entirely at a predetermined temperature (800 to 1200°) by the heater unit 10, high purity oxygen (O₂) as processing gas is supplied at a predetermined flow rate into the processing chamber 4 by the gas introducing tube 9, and a good-quality oxide film is formed on the wafer 20. At that time, the pressure in the preliminary chamber 14 is maintained higher than that of the processing chamber 4, and the cap 11 is strongly pushed to be contacted with the seal flange 30 by the pressure difference. Therefore, hermeticity of the processing chamber 4 can be maintained at extremely high level.

Then, when a preset processing time is elapsed, the cap 11 supporting the boat 21 is lowered by the elevator 12, the cap is separated from the lower surface of the seal flange to open the opening 31, and the boat 21 is transferred out from the processing chamber 4 into the preliminary chamber 14. When the cap 11 is separated from the lower surface of the seal flange 30, if the pressure in the preliminary chamber 14 is higher than that of the processing chamber 4, the cap 11 can not be separated from the lower surface of the seal flange 30. That is, the boat 21 can not be lowered following the lowering movement of the elevator 12.

Thereupon, in the present embodiment, the pressure in the preliminary chamber 14 and the pressure in the processing chamber 4 are adjusted into balance substantially, the state in which the cap 11 is pushed to be contacted with the seal flange 30 by the pressure difference between the preliminary chamber 14 and the processing chamber 4 is released. The pressure in the preliminary chamber 14 and the pressure in the processing chamber 4 may be brought into balance by introducing the nitrogen gas into the processing chamber 4 from the gas introducing tube 9, or by discharging the nitrogen gas in the preliminary chamber 14 from the exhaust port 19. In this regard, after the cap 11 is separated from the seal flange 30, if the pressure in the preliminary chamber 14 is adjusted to be slightly higher than that of in the processing chamber 4, it is possible to prevent the ambience in the processing chamber 4 from leaking into the preliminary chamber 14.

When the boat 21 reaches the lower limit, the lower surface of the seal portion 36 of the seal lid 35 seats on the lower surface of the seal flange 30 with the seal ring 34 interposed therebetween, and the opening 31 of the seal flange 30 is closed in the sealed state. Therefore, the processing chamber 4 and the preliminary chamber 14 are cut off from each other in terms of fluid. When the seal lid 35 seats on the seal flange 30 to close the opening 31 thereby bringing the processing chamber 4 into its sealed (air-tightly sealed) state, the pressure in the processing chamber 4 is adjusted slightly higher than that in the preliminary chamber 14, and the sealed state of the processing chamber 4 by the seal lid 35 is reliably maintained.

Then, when the gate valve 17 is opened, the wafers 20 held by the boat 21 are taken out by the wafer transfer apparatus, and the wafers 20 are transferred out from the preliminary chamber 14 through the wafer load-unload port 15. At that time, since the nitrogen gas atmosphere is formed in the preliminary chamber 14, the wafers 20 after transferred out from the processing chamber 4 are not brought into contact with atmospheric air and do not undergo oxidation by oxygen or moisture included in the atmosphere, and unnecessary oxide film is reliably prevented from being formed on the wafer 20.

Thereafter, the above-described operation is repeated.

The following Table 1 shows one example of relation between pressure in the processing chamber 4 and pressure in the preliminary chamber 14 when the opening 31 of the seal flange 30 is closed by the seal lid 35 and when the boat 21 is transferred in and out, with respect to a normal pressure processing and a reduced pressure processing of the heat treatment apparatus.

TABLE 1

| | | Normal | Reduced |
|---|---|---|---|
| | | pressure | pressure |
| | | processing | processing |
| When sealed | Processing | Atmospheric | Atmospheric |
| | chamber | pressure | pressure |
| | Preliminary | Reduced | Reduced |
| | chamber | pressure | pressure |
| When | Processing | Atmospheric | Atmospheric |
| transferred | chamber | pressure | pressure/Reduced |
| in and out | | | pressure |
| | Preliminary | Atmospheric | Atmospheric |
| | chamber | pressure | pressure/Reduced |
| | | | pressure |

According to the above-mentioned embodiment, the following effects can be obtained.

1) When the boat is on standby in the preliminary chamber, the seal lid seats on the seal flange to close the opening and thus, the processing chamber and the preliminary chamber are cut off from each other. Therefore, inert atmosphere can be formed in the preliminary chamber.

2) By making the preliminary chamber to be the inert atmosphere, it is possible to prevent the wafer from coming into contact with atmospheric air while the boat is on standby in the preliminary chamber, and to prevent the wafer from undergoing oxidation by oxygen or moisture included in the atmospheric air. Therefore, unnecessary oxide film is reliably prevented from being formed on the wafer. As a result, the precision of heat treatment of the heat treatment apparatus can be enhanced, and quality and reliability of a semiconductor device produced by the wafer can be enhanced.

3) When the boat lifts up the seal lid when the boat is transferred into the processing chamber from the preliminary chamber, the seal lid can be separated from the seal flange to automatically open the opening of the seal flange. Therefore, a driving apparatus required for opening and closing the opening of the seal flange by the seal lid can be eliminated.

4) By eliminating the driving apparatus required for opening and closing the opening of the seal flange by the seal lid, it is possible to prevent dust caused by the driving apparatus from being generated. Therefore, it is possible to prevent a foreign substance from adhering to the wafer during heat treatment of the heat treatment apparatus to enhance the precision of the heat treatment of the heat treatment apparatus, and quality and reliability of a semiconductor device produced by the wafer can be enhanced.

5) By eliminating the driving apparatus required for opening and closing the opening of the seal flange by the seal lid, the producing cost and running cost for the heat treatment apparatus can be reduced by the amount of eliminating at least the driving apparatus and software of a controller required for controlling the driving apparatus, and the like.

6) By adjusting the pressure in the preliminary chamber when the opening of the seal flange is closed by the seal lid higher than the pressure in the processing chamber, the seal lid can be pushed to come into contact with the seal flange. Therefore, it is possible to reliably cut off the preliminary chamber and the processing chamber from each other by the seal lid.

7) By adjusting the pressure in the preliminary chamber equal to or higher than the pressure in the processing chamber when the boat separates the seal lid from the seal flange, the seal lid can easily be separated from the seal flange by hoisting the boat.

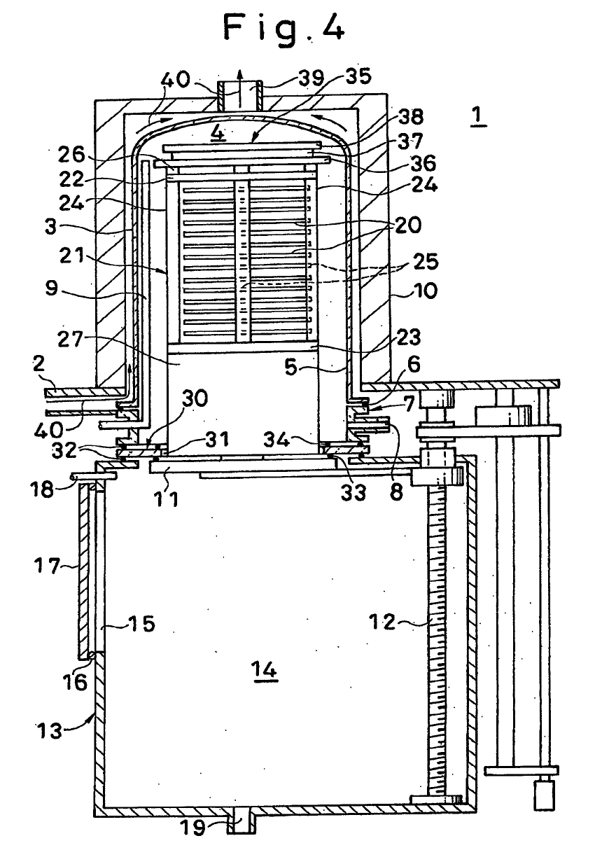

FIG. 4 is a front sectional view showing a heat treatment apparatus according to another embodiment of the present invention.

This embodiment is different from the above-mentioned embodiment in that an exhaust port 39 for exhausting air 40 as refrigerant is formed in a top portion of the heater unit 10 at a position opposed to the seal lid 35 with the process tube 3 interposed therebetween, and this exhaust port 39 is connected in terms of fluid to an exhaust apparatus (not shown) such as a blower.

When the exhausting force of the exhausting apparatus is applied to the exhausting port 39 in a state in which the boat 21 holding wafers 20 is transferred into the processing chamber 4 as shown in FIG. 4, the air 40 is taken into a gap between the heater unit 10 and the process tube 3 from an opening of the machine frame 2 formed at a lower end of the heater unit 10, and the air 40 comes into contact with the heater unit 10 and the process tube 3, and the air 40 is exhausted from the exhaust port 39 while absorbing heat. Therefore, the processing chamber 4 can be cooled rapidly.

If the exhaust port 39 is formed in the top portion of the heater unit 10, heat is leaked locally around the exhaust port 39, and the wafers 20 held by the boat 21 of the processing chamber 4 are not heated uniformly. That is, a temperature of a wafer located at an upper portion of the boat 21 is lower than that of a wafer located at another portion of the boat 21.

However, in the present embodiment, since the seal lid 35 is disposed on the boat 21 during the heat treatment of the processing chamber 4, an adverse influence due to heat leakage of the exhaust port 39 can be avoided or reduced by the heat insulation effect of the seal lid 35. That is, the seal lid 35 absorbs the influence caused by heat leakage of the exhaust port 39 by the heat insulation effect such as heat shielding effect and uniformly heating effect by great thermal capacity. As a result, the heat leaked from the exhaust port 39 can be prevented from being transferred to the wafer 20 located at the upper portion in the boat 21.

Therefore, according to the present embodiment, even when the exhaust port 39 is formed in the heater unit 10, a wafer 20 located at an upper portion in the boat 21 can be heated under the same condition as that of a wafer 20 located at another portion in the boat 21 and thus, it is possible to maintain the uniformity of the heat treatment of wafers 20 over the entire length of the boat 21.

In other words, even when the exhaust port 39 is formed in the heater unit 10, since the uniformity of the heat treatment of the wafers 20 can be secured by the seal lid 35, it is possible to form the exhaust port 39 in the heater unit 10. By forming the exhaust port 39 in the heater unit 10, there is effect that it is possible to enhance the rapidly heating and rapidly cooling performance of the heater unit 10.

The present invention is not limited to the above embodiments, and it is of course possible to make various modifications without departing from the subject matter.

For example, the seal lid is not limited to one comprising the seal portion, the rib portion and the heat insulating portion. The rib portion and the heat insulating portion may be omitted if unnecessary.

The heat treatment apparatus is not limited to one for forming the oxide film, and the heat treatment apparatus can be used for heat treatment such as diffusion processing and anneal processing.

Although the embodiments have been described based on the batch-type vertical-type hot wall-type heat treatment apparatus, the present invention is not limited to this, and the present invention can be applied to a substrate processing apparatus comprising a processing chamber and a preliminary chamber such as a batch-type vertical-type hot wall-type CVD (Chemical Vapor Deposition) apparatus and the like.

Although the wafers are subjected to the heat treatment in the above-mentioned embodiments, the present invention can be applied to a case in which the wafers are subjected to film formation processing, and the substrate to be processed may be a glass substrate for producing a liquid crystal panel or the like.

As explained above, according to the present invention, it is possible to enhance precision of substrate processing while preventing dust from being generated and to prevent costs from increasing.

The entire disclosure of Japanese Patent Application No. 2000-060875 filed on Mar. 6, 2000 including specification, claims, drawings and summary are incorporated herein by reference in its entirety.

Although various exemplary embodiments have been shown and described, the invention is not limited to the embodiments shown. Therefore, the scope of the invention is intended to be limited solely by the scope of the claims that follow.

What is claimed is:

1. A substrate processing apparatus, comprising:
a process tube for forming a processing chamber provided at its lower end with a furnace port;
a boat for going in and out from said processing chamber to transfer a substrate or substrates into and out from said processing chamber;
a chamber forming a preliminary chamber and disposed below said processing tube for staying said boat on standby, a seal flange disposed between said processing chamber and said preliminary chamber and having an opening through which said boat passes; and
a seal lid detachably disposed on said seal flange at the side of said processing chamber for seating on said seal flange to air-tightly close said opening.

2. A substrate processing apparatus according to claim 1, wherein said seal lid comprises a seal portion for air-tightly closing said opening of said seal flange, and a rib portion for reinforcing said seal portion.

3. A substrate processing apparatus according to claim 1, further comprising a heater unit disposed outside of said process tube for heating said processing chamber, wherein an exhaust port for exhaust refrigerant is formed in said heater unit at a location opposed to said seal lid with said process tube disposed therebetween.

4. A substrate processing method comprising the step of processing a substrate or substrates using a substrate processing apparatus, comprising:
a process tube for forming a processing chamber provided at its lower end with a furnace port;
a boat for going in and out from said processing chamber to transfer said substrate or said substrates into and out from said processing chamber;
a chamber forming a preliminary chamber and disposed below said processing tube for staying said boat on standby, a seal flange disposed between said processing chamber and said preliminary chamber and having an opening through which said boat passes; and
a seal lid detachably disposed on said seal flange at the side of said processing chamber for seating on said seal flange to air-tightly close said opening.

5. A substrate processing method according to claim 4, wherein pressure in said preliminary chamber when said seal lid closes said opening of said seal flange is set lower than pressure in said processing chamber.

6. A substrate processing method according to claim 4, wherein when said boat separates said seal lid from said seal flange, pressure in said preliminary chamber is set equal to or greater than pressure in said processing chamber.

7. An electronic device manufacturing method comprising the step of processing a substrate or substrates using a substrate processing apparatus, comprising:
a process tube for forming a processing chamber provided at its lower end with a furnace port;
a boat for going in and out from said processing chamber to transfer said substrate or said substrates into and out from said processing chamber;
a chamber forming a preliminary chamber and disposed below said processing tube for staying said boat on standby,
a seal flange disposed between said processing chamber and said preliminary chamber and having an opening through which said boat passes; and
a seal lid detachably disposed on said seal flange at the side of said processing chamber for seating on said seal flange to air-tightly close said opening.
